(19) United States
(12) Patent Application Publication
(10) Pub. No.: US 2024/0421125 A1
(43) Pub. Date: Dec. 19, 2024

(54) SEMICONDUCTOR PACKAGE

(71) Applicant: Samsung Electronics Co., Ltd., Suwon-si (KR)

(72) Inventor: SEUNGDUK BAEK, Suwon-si (KR)

(21) Appl. No.: 18/541,649

(22) Filed: Dec. 15, 2023

(30) Foreign Application Priority Data
Jun. 15, 2023 (KR) 10-2023-0076834

(51) Int. Cl. H01L 25/065; H01L 23/00; H01L 23/31; H01L 23/48; H01L 23/538; H10B 80/00

(52) U.S. Cl. CPC H01L 25/0655; H01L 23/3157; H01L 23/481; H01L 23/5383; H01L 23/5384; H01L 23/5385; H01L 24/08; H10B 80/00; H01L 2224/08145; H01L 2224/08225

(57) ABSTRACT

A semiconductor package includes an interposer, a first semiconductor chip on the interposer, a connection structure on the interposer, and a second semiconductor chip on the first semiconductor chip and the connection structure. The first semiconductor chip includes a first input/output circuit. The second semiconductor chip includes a second input/output circuit. The connection structure includes a connection substrate, and a connection through-via penetrating the connection substrate and electrically connecting the second semiconductor chip and the interposer. The first input/output circuit and the second input/output circuit are electrically connected to each other.

### CROSS-REFERENCE TO RELATED APPLICATIONS

This U.S. non-provisional patent application claims priority under 35 U.S.C. § 119 to Korean Patent Application No. 10-2023-0076834, filed on Jun. 15, 2023, in the Korean Intellectual Property Office, the entire content of which is hereby incorporated by reference.

### BACKGROUND OF THE INVENTION

The present disclosure relates to a semiconductor package, and more particularly, to a semiconductor package including a connection structure and a method of manufacturing the same.

An integrated circuit chip may be realized in the form of a semiconductor package so as to be appropriately applied to an electronic product. In a typical semiconductor package, a semiconductor chip may be mounted on a printed circuit board and may be electrically connected to the printed circuit board through bonding wires or bumps. Various techniques for improving reliability of semiconductor packages have been studied with the development of an electronic industry.

### SUMMARY

Embodiments of the inventive concepts may provide a semiconductor package with improved electrical characteristics and reliability and a method of manufacturing the same.

In an aspect, a semiconductor package may include an interposer, a first semiconductor chip on the interposer, a connection structure on the interposer, and a second semiconductor chip on the first semiconductor chip and the connection structure. The first semiconductor chip may include a first substrate, a first interconnection structure on a top surface of the first substrate, and a first input/output circuit between the first substrate and the first interconnection structure. The second semiconductor chip may include a second interconnection structure, a second substrate on a top surface of the second interconnection structure, and a second input/output circuit between the second substrate and the second interconnection structure. The connection structure may include a connection substrate, and a connection through-via penetrating the connection substrate and electrically connecting the second semiconductor chip and the interposer. The first input/output circuit and the second input/output circuit may be electrically connected to each other.

In an aspect, a semiconductor package may include an interposer, a first semiconductor chip on the interposer, a connection structure on the interposer, and a second semiconductor chip on the first semiconductor chip and the connection structure. The second semiconductor chip may overlap with the first semiconductor chip and the connection structure. A height of the first semiconductor chip may be equal to a height of the connection structure.

In an aspect, a semiconductor package may include an interposer, a first semiconductor chip on the interposer, a connection structure on the interposer, an insulating layer surrounding the first semiconductor chip and the connection structure, a second semiconductor chip on the first semiconductor chip and the connection structure, third semiconductor chips on the second semiconductor chip, a dummy semiconductor chip on the first semiconductor chip, and a molding layer surrounding the dummy semiconductor chip, the second semiconductor chip and the third semiconductor chips. The first semiconductor chip may include a first substrate, a first interconnection structure on a top surface of the first substrate, a first input/output circuit between the first substrate and the first interconnection structure, and an upper pad electrically connected to the first input/output circuit. The second semiconductor chip may include a second interconnection structure, a second substrate on a top surface of the second interconnection structure, a second input/output circuit between the second substrate and the second interconnection structure, and a lower pad electrically connected to the second input/output circuit. The connection structure may include a connection substrate, and a connection through-via penetrating the connection substrate and electrically connecting the second semiconductor chip to the interposer. A top surface of the upper pad may be in contact with a bottom surface of the lower pad.

In an aspect, a method of manufacturing a semiconductor package may include forming an interposer, forming a first semiconductor chip and a connection structure on the interposer, and forming a second semiconductor chip on the first semiconductor chip and the connection structure. The connection structure may include a connection substrate, and a connection through-via penetrating the connection substrate.

### BRIEF DESCRIPTION OF THE DRAWINGS

FIG. 1A is a cross-sectional view illustrating a semiconductor package according to some embodiments of the inventive concepts.

FIG. 1B is an enlarged view of a region ‘A’ of FIG. 1A.

FIGS. 2A, 2B, 2C, 2D and 2E are cross-sectional views illustrating a method of manufacturing a semiconductor package according to some embodiments of the inventive concepts.

FIGS. 3A and 3B are cross-sectional views illustrating a method of manufacturing a semiconductor package according to some embodiments of the inventive concepts.

FIG. 4 is a cross-sectional view illustrating a semiconductor package according to some embodiments of the inventive concepts.

FIGS. 5A and 5B are cross-sectional views illustrating a method of manufacturing a semiconductor package according to some embodiments of the inventive concepts.

FIG. 6 is an enlarged cross-sectional view illustrating a semiconductor package according to some embodiments of the inventive concepts.

### DETAILED DESCRIPTION

Embodiments of the inventive concepts will now be described more fully with reference to the accompanying drawings.

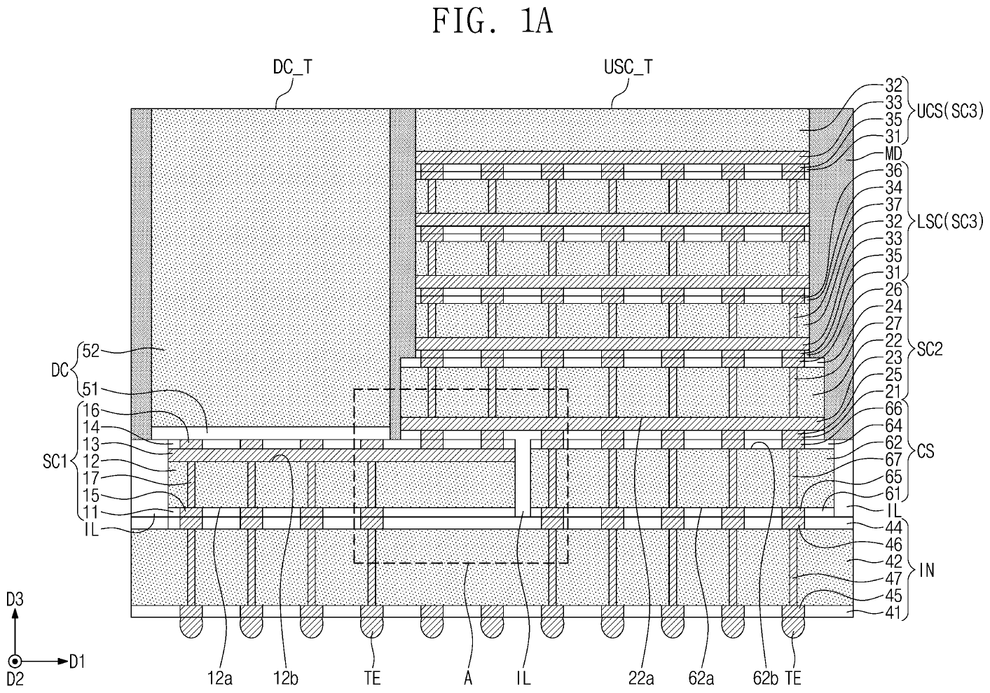

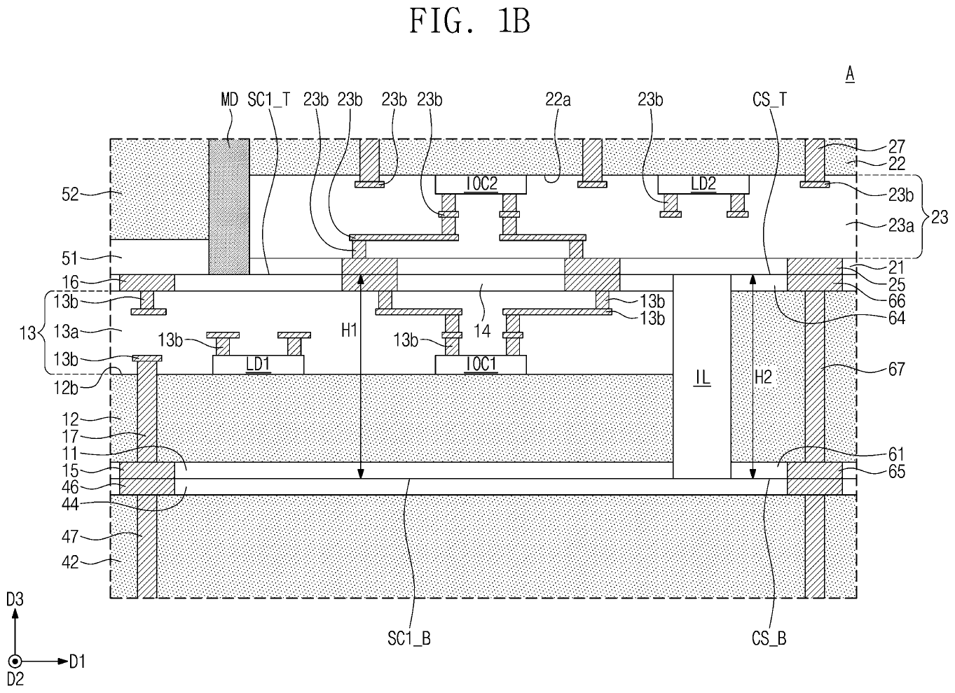

FIG. 1A is a cross-sectional view illustrating a semiconductor package according to some embodiments of the inventive concepts. FIG. 1B is an enlarged view of a region ‘A’ of FIG. 1A.

Referring to FIG. 1A, a semiconductor package may include an interposer IN, a first semiconductor chip SC1, a connection structure CS, a second semiconductor chip SC2, a plurality of third semiconductor chips SC3, a dummy semiconductor chip DC, a molding layer MD, an insulating layer IL, and terminals TE.

The first semiconductor chip SC1 may be provided on the interposer IN. The first semiconductor chip SC1 may include a first lower protective layer 11, a first substrate 12 on the first lower protective layer 11, a first interconnection structure 13 on the first substrate 12, a first upper protective layer 14 on the first interconnection structure 13, first lower pads 15 in the first lower protective layer 11, first upper pads 16 in the first upper protective layer 14, and first through-vias 17 penetrating the first substrate 12.

The first substrate 12 may have a plate shape extending along a plane defined by a first direction D1 and a second direction D2. The first direction D1 and the second direction D2 may intersect each other. For example, the first direction D1 and the second direction D2 may be horizontal directions perpendicular to each other. The first substrate 12 may be a semiconductor substrate. For example, the first substrate 12 may include silicon, germanium, silicon-germanium, gallium-phosphorus, or gallium-arsenic. In certain embodiments, the first substrate 12 may be a silicon-on-insulator (SOI) substrate or a germanium-on-insulator (GOI) substrate.

The first lower protective layer 11 may cover a bottom surface 12a of the first substrate 12. The first lower protective layer 11 may include an insulating material. For example, the first lower protective layer 11 may include an oxide. In some embodiments, the first lower protective layer 11 may be a multi-layer including a plurality of insulating layers.

The first interconnection structure 13 may be provided on a top surface 12b of the first substrate 12. The first interconnection structure 13 may cover the top surface 12b of the first substrate 12.

The first upper protective layer 14 may cover a top surface of the first interconnection structure 13. The first upper protective layer 14 may include an insulating material. For example, the first upper protective layer 14 may include an oxide. In some embodiments, the first upper protective layer 14 may be a multi-layer including a plurality of insulating layers.

The first lower pads 15 may be surrounded by the first lower protective layer 11. The first lower pads 15 may include a conductive material. For example, the first lower pads 15 may include copper.

The first upper pads 16 may be surrounded by the first upper protective layer 14. The first upper pads 16 may include a conductive material. For example, the first upper pads 16 may include copper.

The first through-via 17 may be connected to the first lower pad 15 and the first interconnection structure 13. The first through-via 17 may penetrate the first substrate 12 in a third direction D3 to electrically connect the first lower pad 15 to the first interconnection structure 13. The third direction D3 may intersect the first direction D1 and the second direction D2. For example, the third direction D3 may be a vertical direction perpendicular to the first direction D1 and the second direction D2. The first through-via 17 may include a conductive material.

The connection structure CS may be provided on the interposer IN. The connection structure CS may be spaced apart from the first semiconductor chip SC1 in the first direction D1.

The connection structure CS may include a lower connection protective layer 61, a connection substrate 62 on the lower connection protective layer 61, an upper connection protective layer 64 on the connection substrate 62, lower connection pads 65 in the lower connection protective layer 61, upper connection pads 66 in the upper connection protective layer 64, and connection through-vias 67 penetrating the connection substrate 62.

The connection substrate 62 may be a semiconductor substrate. In certain embodiments, the connection substrate 62 may be a silicon-on-insulator (SOI) substrate or a germanium-on-insulator (GOI) substrate.

The lower connection protective layer 61 may cover a bottom surface 62a of the connection substrate 62. The lower connection protective layer 61 may include an insulating material. For example, the lower connection protective layer 61 may include an oxide. In some embodiments, the lower connection protective layer 61 may be a multi-layer including a plurality of insulating layers.

The upper connection protective layer 64 may cover a top surface 62b of the connection substrate 62. The upper connection protective layer 64 may include an insulating material. For example, the upper connection protective layer 64 may include an oxide. In some embodiments, the upper connection protective layer 64 may be a multi-layer including a plurality of insulating layers.

The lower connection pads 65 may be surrounded by the lower connection protective layer 61. The lower connection pads 65 may include a conductive material. For example, the lower connection pads 65 may include copper.

The upper connection pads 66 may be surrounded by the upper connection protective layer 64. The upper connection pads 66 may include a conductive material. For example, the upper connection pads 66 may include copper.

The connection through-via 67 may be connected to the lower connection pad 65 and the upper connection pad 66. The connection through-via 67 may penetrate the connection substrate 62 in the third direction D3 so as to be electrically connected to the lower connection pad 65 and the upper connection pad 66. The second semiconductor chip SC2 and the interposer IN may be electrically connected to each other through the upper connection pad 66, the connection through-via 67 and the lower connection pad 65. The connection through-via 67 may include a conductive material.

In some embodiments, the connection structure CS may further include a semiconductor device. For example, the connection structure CS may include a logic semiconductor device, an electrostatic discharge (ESD) diode, or a decoupling capacitor.

The insulating layer IL may surround the first semiconductor chip SC1 and the connection structure CS. The insulating layer IL may be provided on the interposer IN. The insulating layer IL may include an inorganic insulating material. For example, the insulating layer IL may include an oxide. The insulating layer IL may not include carbon. A portion of the insulating layer IL may be disposed between the first semiconductor chip SC1 and the connection structure CS.

The second semiconductor chip SC2 may be provided on the first semiconductor chip SC1 and the connection structure CS. The second semiconductor chip SC2 may overlap with the first semiconductor chip SC1 and the connection structure CS in the third direction D3.

The second semiconductor chip SC2 may include a second lower protective layer 21, a second interconnection structure 23 on the second lower protective layer 21, a second substrate 22 on the second interconnection structure 23, a second upper protective layer 24 on the second substrate 22, second lower pads 25 in the second lower protective layer 21, second upper pads 26 in the second upper protective layer 24, and second through-vias 27 penetrating the second substrate 22.

The second substrate 22 may be a semiconductor substrate. In some embodiments, the second substrate 22 may be a silicon-on-insulator (SOI) substrate or a germanium-on-insulator (GOI) substrate.

The second lower protective layer 21 may cover a bottom surface of the second interconnection structure 23. A bottom surface of the second lower protective layer 21 may be in contact with a top surface of the first upper protective layer 14 and a top surface of the upper connection protective layer 64. The second lower protective layer 21 may include an insulating material. For example, the second lower protective layer 21 may include an oxide. In some embodiments, the second lower protective layer 21 may be a multi-layer including a plurality of insulating layers. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting,” “in contact with,” or “contact” another element, there are no intervening elements present at the point of contact.

The second interconnection structure 23 may cover a bottom surface 22a of the second substrate 22. The second substrate 22 may be provided on a top surface of the second interconnection structure 23. The bottom surface 22a of the second substrate 22 may face the top surface 12b of the first substrate 12 and the top surface 62b of the connection substrate 62.

The second upper protective layer 24 may cover a top surface of the second substrate 22. The second upper protective layer 24 may include an insulating material. For example, the second upper protective layer 24 may include an oxide. In some embodiments, the second upper protective layer 24 may be a multi-layer including a plurality of insulating layers.

The second lower pads 25 may be surrounded by the second lower protective layer 21. A bottom surface of the second lower pad 25 may face a top surface of the first upper pad 16 or a top surface of the upper connection pad 66. The bottom surface of the second lower pad 25 may be in contact with the top surface of the first upper pad 16 or the top surface of the upper connection pad 66. The second semiconductor chip SC2 may be bonded to the first semiconductor chip SC1 and the connection structure CS by a hybrid bonding method. The first upper pads 16 and the second lower pads 25, which are connected to each other, may be symmetrically disposed. The second lower pads 25 may include a conductive material. For example, the second lower pads 25 may include copper.

The second upper pads 26 may be surrounded by the second upper protective layer 24. The second upper pads 26 may include a conductive material. For example, the second upper pads 26 may include copper.

The second through-via 27 may be connected to the second upper pad 26 and the second interconnection structure 23. The second through-via 27 may penetrate the second substrate 22 in the third direction D3 to electrically connect the second upper pad 26 to the second interconnection structure 23. The second through-via 27 may include a conductive material.

The third semiconductor chips SC3 may be provided on the second semiconductor chip SC2. The third semiconductor chips SC3 may be stacked in the third direction D3. However, the number of the third semiconductor chips SC3 is not limited to the illustration of FIG. 1A. In certain embodiments, the number of the third semiconductor chips SC3 may be five or more.

One or more of the third semiconductor chips SC3 (i.e., “the third semiconductor chip SC3”) may include a third lower protective layer 31, a third interconnection structure 33 on the third lower protective layer 31, a third substrate 32 on the third interconnection structure 33, a third upper protective layer 34 on the third substrate 32, third lower pads 35 in the third lower protective layer 31, third upper pads 36 in the third upper protective layer 34, and third through-vias 37 penetrating the third substrate 32.

The third substrate 32 may be a semiconductor substrate. In certain embodiments, the third substrate 32 may be a silicon-on-insulator (SOI) substrate or a germanium-on-insulator (GOI) substrate.

The third lower protective layer 31 may cover a bottom surface of the third interconnection structure 33. A bottom surface of the third lower protective layer 31 may be in contact with a top surface of the second upper protective layer 24. The third lower protective layer 31 may include an insulating material. For example, the third lower protective layer 31 may include an oxide. In some embodiments, the third lower protective layer 31 may be a multi-layer including a plurality of insulating layers.

The third interconnection structure 33 may cover a bottom surface of the third substrate 32. The third semiconductor chip SC3 may be a memory semiconductor chip including a memory semiconductor device. The memory semiconductor device of the third semiconductor chip SC3 may be provided between the third interconnection structure 33 and the third substrate 32.

The third upper protective layer 34 may cover a top surface of the third substrate 32. The third upper protective layer 34 may include an insulating material. For example, the third upper protective layer 34 may include an oxide. In some embodiments, the third upper protective layer 34 may be a multi-layer including a plurality of insulating layers.

The third lower pads 35 may be surrounded by the third lower protective layer 31. The third lower pads 35 may include a conductive material. For example, the third lower pads 35 may include copper.

The third upper pads 36 may be surrounded by the third upper protective layer 34. The third upper pads 36 may include a conductive material. For example, the third upper pads 36 may include copper.

The third through-via 37 may be connected to the third upper pad 36 and the third interconnection structure 33. The third through-via 37 may penetrate the third substrate 32 in the third direction D3 to electrically connect the third upper pad 36 to the third interconnection structure 33. The third through-via 37 may include a conductive material.

An uppermost one of the plurality of third semiconductor chips SC3 may be defined as an uppermost semiconductor chip USC. The uppermost semiconductor chip USC may not include the third upper protective layer 34, the third upper pad 36 and the third through-via 37.

A lowermost one of the plurality of third semiconductor chips SC3 may be defined as a lowermost semiconductor chip LSC. The lowermost semiconductor chip LSC may be bonded to the second semiconductor chip SC2 by the hybrid bonding method. The third semiconductor chips SC3 may be bonded to each other by the hybrid bonding method.

The dummy semiconductor chip DC may be provided on the first semiconductor chip SC1. The dummy semiconductor chip DC may include a dummy protective layer 51 and a dummy substrate 52 on the dummy protective layer 51.

The dummy substrate 52 may be a semiconductor substrate. In certain embodiments, the dummy substrate 52 may be a silicon-on-insulator (SOI) substrate or a germanium-on-insulator (GOI) substrate.

The dummy protective layer 51 may cover a bottom surface of the dummy substrate 52. A bottom surface of the dummy protective layer 51 may be in contact with the top surface of the first upper protective layer 14 and the top surface of at least one of the first upper pads 16. The dummy protective layer 51 may include an insulating material. For example, the dummy protective layer 51 may include an oxide. In some embodiments, the dummy protective layer 51 may be a multi-layer including a plurality of insulating layers.

Although not illustrated, in some embodiments, the dummy semiconductor chip DC may further include dummy pads surrounded by the dummy protective layer 51. In this case, a bottom surface of the dummy pad may be in contact with the top surface of a corresponding one of the first upper pads 16.

In some embodiments, the dummy semiconductor chip DC may further include an adhesive layer between the dummy protective layer 51 and the first upper protective layer 14 of the first semiconductor chip SC1. A thermal conductivity of the adhesive layer may be lower than thermal conductivities of the dummy substrate 52 and the dummy protective layer 51. For example, the adhesive layer may include a thermal interface material (TIM).

A top surface DC_T of the dummy semiconductor chip DC may be coplanar with a top surface USC_T of the uppermost semiconductor chip USC. A level of the top surface DC_T of the dummy semiconductor chip DC may be the same as a level of the top surface USC_T of the uppermost semiconductor chip USC. A distance in the third direction D3 between the top surface DC_T of the dummy semiconductor chip DC and the interposer IN may be equal to a distance in the third direction D3 between the top surface USC_T of the uppermost semiconductor chip USC and the interposer IN. The top surface DC_T of the dummy semiconductor chip DC may be a top surface of the dummy substrate 52. The top surface USC_T of the uppermost semiconductor chip USC may be a top surface of the third substrate 32 of the uppermost semiconductor chip USC. Terms such as “same,” “equal,” “planar,” or “coplanar,” as used herein encompass identicality or near identicality including variations that may occur, for example, due to manufacturing processes. The term “substantially” may be used herein to emphasize this meaning, unless the context or other statements indicate otherwise.

The molding layer MD may be provided to surround the dummy semiconductor chip DC, the second semiconductor chip SC2 and the third semiconductor chips SC3. The molding layer MD may be provided on the insulating layer IL. The molding layer MD may include an organic insulating material including carbon. For example, the molding layer MD may include an epoxy molding compound (EMC). A top surface of the molding layer MD may be coplanar with the top surface DC_T of the dummy semiconductor chip DC and the top surface USC_T of the uppermost semiconductor chip USC.

The interposer IN may include a fourth lower protective layer 41, a fourth substrate 42 on the fourth lower protective layer 41, a fourth upper protective layer 44 on the fourth substrate 42, fourth lower pads 45 in the fourth lower protective layer 41, fourth upper pads 46 in the fourth upper protective layer 44, and fourth through-vias 47 penetrating the fourth substrate 42.

The fourth substrate 42 may be a semiconductor substrate. In certain embodiments, the fourth substrate 42 may be a silicon-on-insulator (SOI) substrate or a germanium-on-insulator (GOI) substrate.

The fourth lower protective layer 41 may cover a bottom surface of the fourth substrate 42. The fourth lower protective layer 41 may include an insulating material. For example, the fourth lower protective layer 41 may include an oxide. In some embodiments, the fourth lower protective layer 41 may be a multi-layer including a plurality of insulating layers.

The fourth upper protective layer 44 may cover a top surface of the fourth substrate 42. The fourth upper protective layer 44 may be in contact with the first lower protective layer 11 of the first semiconductor chip SC1, the lower connection protective layer 61 of the connection structure CS, and the insulating layer IL. The fourth upper protective layer 44 may include an insulating material. For example, the fourth upper protective layer 44 may include an oxide. In some embodiments, the fourth upper protective layer 44 may be a multi-layer including a plurality of insulating layers.

The fourth lower pads 45 may be surrounded by the fourth lower protective layer 41. The terminal TE may be in contact with a bottom surface of the fourth lower pad 45. The fourth lower pads 45 may include a conductive material. For example, the fourth lower pads 45 may include copper.

The fourth upper pads 46 may be surrounded by the fourth upper protective layer 44. A top surface of the fourth upper pad 46 may be in contact with a bottom surface of the first lower pad 15 of the first semiconductor chip SC1 or a bottom surface of the lower connection pad 65 of the connection structure CS. The interposer IN may be bonded to the first semiconductor chip SC1 and the connection structure CS by the hybrid bonding method. The fourth upper pads 46 may include a conductive material. For example, the fourth upper pads 46 may include copper.

The fourth through-via 47 may be connected to the fourth upper pad 46 and the fourth lower pad 45. The fourth through-via 47 may penetrate the fourth substrate 42 in the third direction D3 to electrically connect the fourth upper pad 46 to the fourth lower pad 45. The fourth through-via 47 may include a conductive material.

In some embodiments, the interposer IN may be a redistribution substrate.

The terminal TE may include a conductive material. The semiconductor package may be electrically connected to an external device through the terminal TE.

Referring to FIG. 1B, the first semiconductor chip SC1 may be a central processing unit (CPU) chip or a graphic processing unit (GPU) chip. The first semiconductor chip SC1 may include a first logic semiconductor device LD1 and a first input/output circuit IOC1. The first logic semiconductor device LD1 and the first input/output circuit IOC1 may be provided on the top surface 12b of the first substrate 12. Each of the first logic semiconductor device LD1 and the first input/output circuit IOC1 may include a transistor provided on the top surface 12b of the first substrate 12. The first logic semiconductor device LD1 and the first input/output circuit IOC1 may be provided between the first interconnection structure 13 and the first substrate 12.

In certain embodiments, the first semiconductor chip SC1 may be a memory semiconductor chip including a memory semiconductor device.

The first interconnection structure 13 may include a first interconnection insulating layer 13a and first conductive structures 13b. The first interconnection insulating layer 13a may be provided on the top surface 12b of the first substrate 12. The first interconnection insulating layer 13a may include an insulating material. In some embodiments, the first interconnection insulating layer 13a may be a multi-layer including a plurality of insulating layers.

The first conductive structures 13b may be provided in the first interconnection insulating layer 13a. The first conductive structures 13b may be surrounded by the first interconnection insulating layer 13a. The first conductive structures 13b may include at least one of a conductive pad, a conductive contact, or a conductive line.

The first through-via 17, the first logic semiconductor device LD1, the first input/output circuit IOC1 and the first upper pad 16 may be connected to the first conductive structures 13b. The first input/output circuit IOC1 may be electrically connected to corresponding one(s) of the first upper pads 16 through corresponding ones of the first conductive structures 13b. The first conductive structures 13b may include a conductive material.

The second semiconductor chip SC2 may be a logic semiconductor chip. The second semiconductor chip SC2 may include a second logic semiconductor device LD2 and a second input/output circuit IOC2. The second logic semiconductor device LD2 and the second input/output circuit IOC2 may be provided on the bottom surface 22a of the second substrate 22. Each of the second logic semiconductor device LD2 and the second input/output circuit IOC2 may include a transistor provided on the bottom surface 22a of the second substrate 22. The second logic semiconductor device LD2 and the second input/output circuit IOC2 may be provided between the second interconnection structure 23 and the second substrate 22.

In certain embodiments, the second semiconductor chip SC2 may be a memory semiconductor chip including a memory semiconductor device.

The second interconnection structure 23 may include a second interconnection insulating layer 23a and second conductive structures 23b. The second interconnection insulating layer 23a may be provided on the bottom surface 22a of the second substrate 22. The second interconnection insulating layer 23a may include an insulating material. In some embodiments, the second interconnection insulating layer 23a may be a multi-layer including a plurality of insulating layers.

The second conductive structures 23b may be provided in the second interconnection insulating layer 23a. The second conductive structures 23b may be surrounded by the second interconnection insulating layer 23a. The second conductive structures 23b may include at least one of a conductive pad, a conductive contact, or a conductive line.

The second through-via 27, the second logic semiconductor device LD2, the second input/output circuit IOC2 and the second lower pad 25 may be connected to the second conductive structures 23b. The second input/output circuit IOC2 may be electrically connected to corresponding one(s) of the second lower pads 25 through corresponding ones of the second conductive structures 23b. The second conductive structures 23b may include a conductive material.

The first input/output circuit IOC1 may be electrically connected to the second input/output circuit IOC2 through the first conductive structures 13b, the first upper pad 16, the second lower pad 25 and the second conductive structures 23b. The first input/output circuit IOC1 and the second input/output circuit IOC2 may overlap with each other in the third direction D3.

The first interconnection structure 13 and the second interconnection structure 23 may be disposed between the top surface 12b of the first substrate 12 and the bottom surface 22a of the second substrate 22. The first input/output circuit IOC1 and the second input/output circuit IOC2 may be disposed between the top surface 12b of the first substrate 12 and the bottom surface 22a of the second substrate 22.

A height H1 of the first semiconductor chip SC1 in the third direction D3 may be equal to a height H2 of the connection structure CS in the third direction D3.

A bottom surface SC1_B of the first semiconductor chip SC1 may be coplanar with a bottom surface CS_B of the connection structure CS. A level of the bottom surface SC1_B of the first semiconductor chip SC1 may be the same as a level of the bottom surface CS_B of the connection structure CS. The bottom surface SC1_B of the first semiconductor chip SC1 may be the bottom surface of the first lower protective layer 11. The bottom surface CS_B of the connection structure CS may be the bottom surface of the lower connection protective layer 61.

A top surface SC1_T of the first semiconductor chip SC1 may be coplanar with a top surface CS_T of the connection structure CS. A level of the top surface SC1_T of the first semiconductor chip SC1 may be the same as a level of the top surface CS_T of the connection structure CS. The top surface SC1_T of the first semiconductor chip SC1 may be the top surface of the first upper protective layer 14. The top surface CS_T of the connection structure CS may be the top surface of the upper connection protective layer 64.

A distance in the third direction D3 between the bottom surface SC1_B and the top surface SC1_T of the first semiconductor chip SC1 may be equal to a distance in the third direction D3 between the bottom surface CS_B and the top surface CS_T of the connection structure CS.

The first semiconductor chip SC1 may include an overlapping portion overlapping with the second semiconductor chip SC2 in the third direction D3. A width of the first semiconductor chip SC1 in the first direction D1 may be equal to or greater than twice a width of the overlapping portion of the first semiconductor chip SC1 in the first direction D1.

A distance in the third direction D3 between the interposer IN and the second semiconductor chip SC2 may be equal to the height H1 of the first semiconductor chip SC1 in the third direction D3 and the height H2 of the connection structure CS in the third direction D3.

The height H1 of the first semiconductor chip SCI in the third direction D3 and the height H2 of the connection structure CS in the third direction D3 may be less than a height of the dummy semiconductor chip DC in the third direction D3.

In the semiconductor package according to the embodiments, the first input/output circuit IOC1 may be disposed on the top surface 12b of the first substrate 12 and the second input/output circuit IOC2 may be disposed on the bottom surface 22a of the second substrate 22, and thus a length of an electrical path connecting the first input/output circuit IOC1 and the second input/output circuit IOC2 may range from several μm to several tens μm. As a result, power and a voltage of an electrical signal between the first input/output circuit IOC1 and the second input/output circuit IOC2 may be reduced to minimize heat generated from the semiconductor package.

In the semiconductor package according to the embodiments, the dummy semiconductor chip DC may be provided on the first semiconductor chip SC1, and thus heat generated from the first semiconductor chip SC1 may be effectively dissipated.

In the semiconductor package according to the embodiments, since the first semiconductor chip SC1 and the second semiconductor chip SC2 are bonded to each other by the hybrid bonding method, pitches of the first upper pads 16 and the second lower pads 25 connected to each other may be reduced and the numbers of the first upper pads 16 and the second lower pads 25 connected to each other may be relatively increased, thereby increasing a bandwidth between the first semiconductor chip SC1 and the second semiconductor chip SC2.

In the semiconductor package according to the embodiments, since the first semiconductor chip SC1 and the second semiconductor chip SC2 are bonded to each other by the hybrid bonding method, the interposer IN may not include a structure connecting the first semiconductor chip SC1 to the second semiconductor chip SC2, and a design of the interposer IN may be simplified.

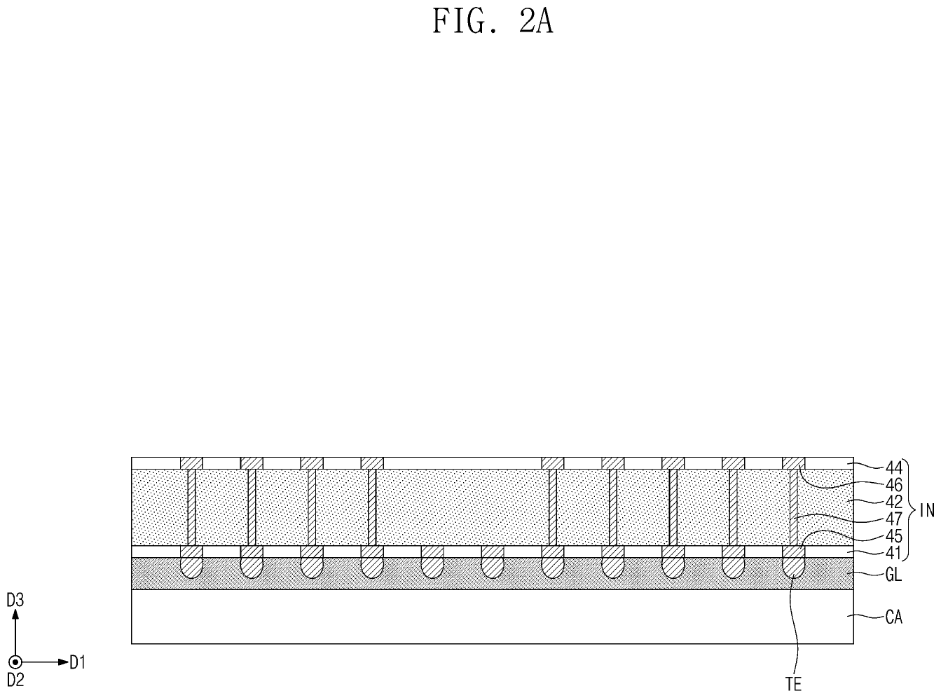

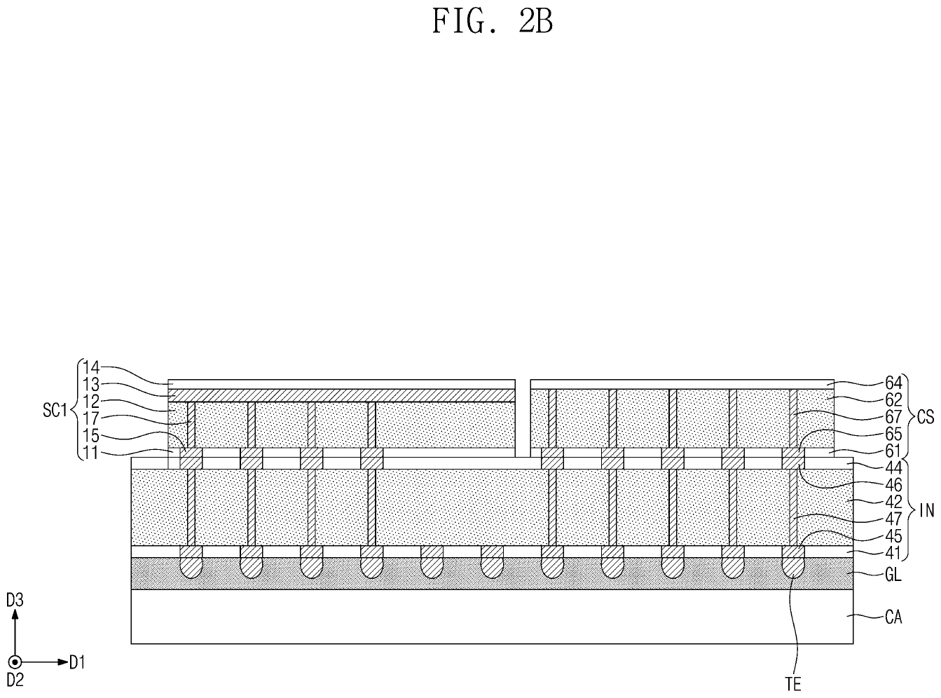

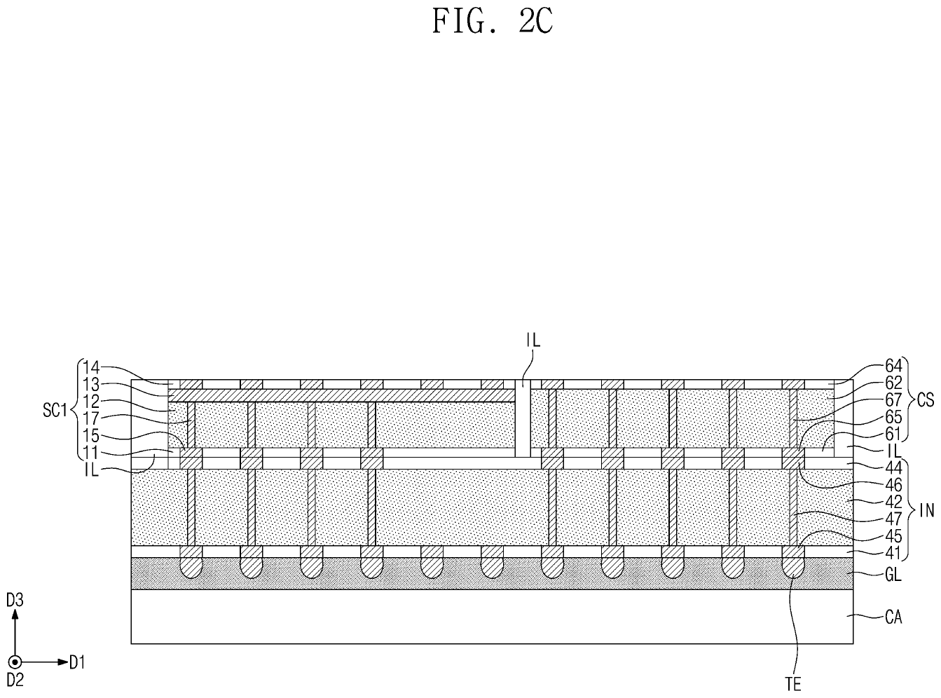

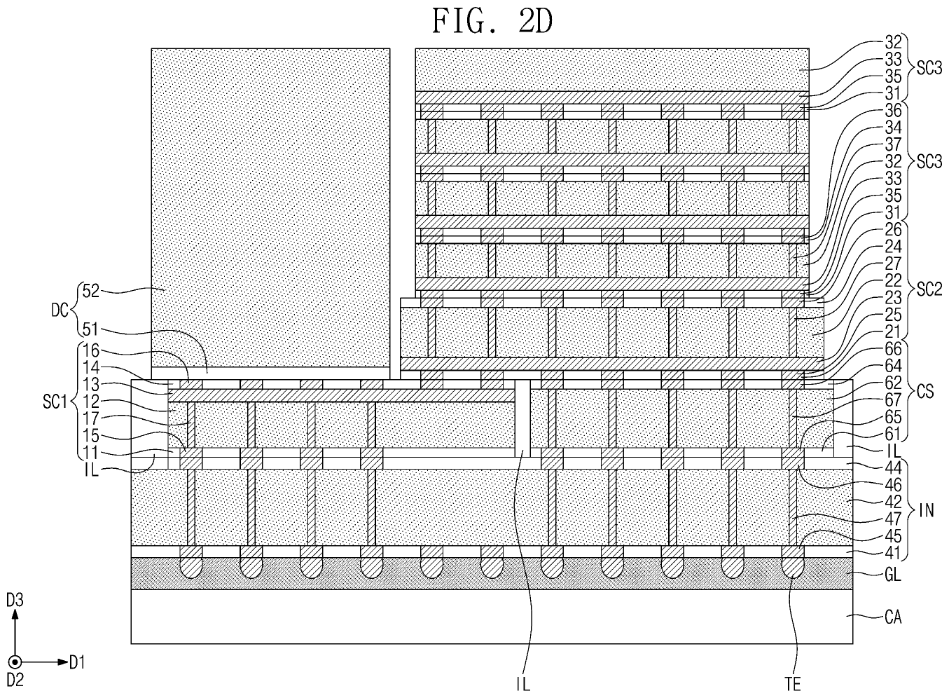

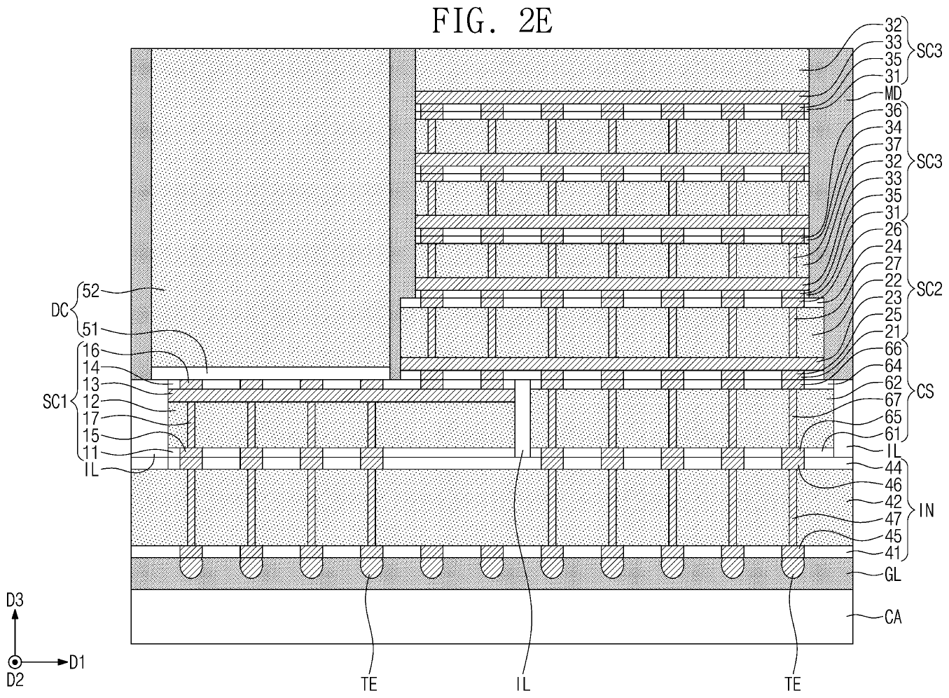

FIGS. 2A, 2B, 2C, 2D and 2E are cross-sectional views illustrating a method of manufacturing a semiconductor package according to some embodiments of the inventive concepts.

Referring to FIG. 2A, a glue layer GL may be formed on a carrier substrate CA. The carrier substrate CA may be a semiconductor substrate or a glass substrate. The glue layer GL may include an adhesive material.

The interposer IN may be formed. A terminal TE may be formed on the fourth lower pad 45 of the interposer IN.

The interposer IN and the terminals TE may be adhered to the glue layer GL.

Referring to FIG. 2B, a first semiconductor chip SC1 and a connection structure CS may be formed on the interposer IN. The first semiconductor chip SC1 and the connection structure CS may be bonded to the interposer IN by a hybrid bonding method. The first lower pad 15 of the first semiconductor chip SC1 may be bonded to a corresponding one of the fourth upper pads 46 of the interposer IN, and the first lower protective layer 11 of the first semiconductor chip SC1 may be bonded to a portion of the fourth upper protective layer 44 of the interposer IN. The lower connection pad 65 of the connection structure CS may be bonded to a corresponding one of the fourth upper pads 46 of the interposer IN, and the lower connection protective layer 61 of the connection structure CS may be bonded to another portion of the fourth upper protective layer 44 of the interposer IN.

Referring to FIG. 2C, an insulating layer IL may be formed to surround the first semiconductor chip SC1 and the connection structure CS. In some embodiments, the formation of the insulating layer IL may include forming a preliminary insulating layer covering the first semiconductor chip SC1 and the connection structure CS, and polishing the preliminary insulating layer to expose the first semiconductor chip SC1 and the connection structure CS.

First upper pads 16 may be formed in the first upper protective layer 14. Upper connection pads 66 may be formed in the upper connection protective layer 64.

Referring to FIG. 2D, a second semiconductor chip SC2 may be formed on the first semiconductor chip SC1 and the connection structure CS. The second semiconductor chip SC2 may be bonded to the first semiconductor chip SC1 and the connection structure CS by the hybrid bonding method. 1. At least one of the second lower pads 25 of the second semiconductor chip SC2 may be bonded to a corresponding one of the first upper pads 16 of the first semiconductor chip SC1, and a portion of the second lower protective layer 21 of the second semiconductor chip SC2 may be bonded to a portion of the first upper protective layer 14 of the first semiconductor chip SC1. At least another of the second lower pads 25 of the second semiconductor chip SC2 may be bonded to the upper connection pad 66 of the connection structure CS, and another portion of the second lower protective layer 21 of the second semiconductor chip SC2 may be bonded to the upper connection protective layer 64 of the connection structure CS.

Third semiconductor chips SC3 may be formed on the second semiconductor chip SC2. The third semiconductor chips SC3 may be formed on the second semiconductor chip SC2 by the hybrid bonding method.

A dummy semiconductor chip DC may be formed on the first semiconductor chip SC1. The dummy protective layer 51 of the dummy semiconductor chip DC may be bonded to corresponding first upper pad(s) 16 and the first upper protective layer 14 of the first semiconductor chip SC1.

Referring to FIG. 2E, a molding layer MD may be formed. In some embodiments, the formation of the molding layer MD may include forming a preliminary molding layer covering the dummy semiconductor chip DC, the second semiconductor chip SC2 and the third semiconductor chips SC3, and grinding the preliminary molding layer.

Referring again to FIG. 1A, the interposer IN and the terminals TE may be separated from the glue layer GL.

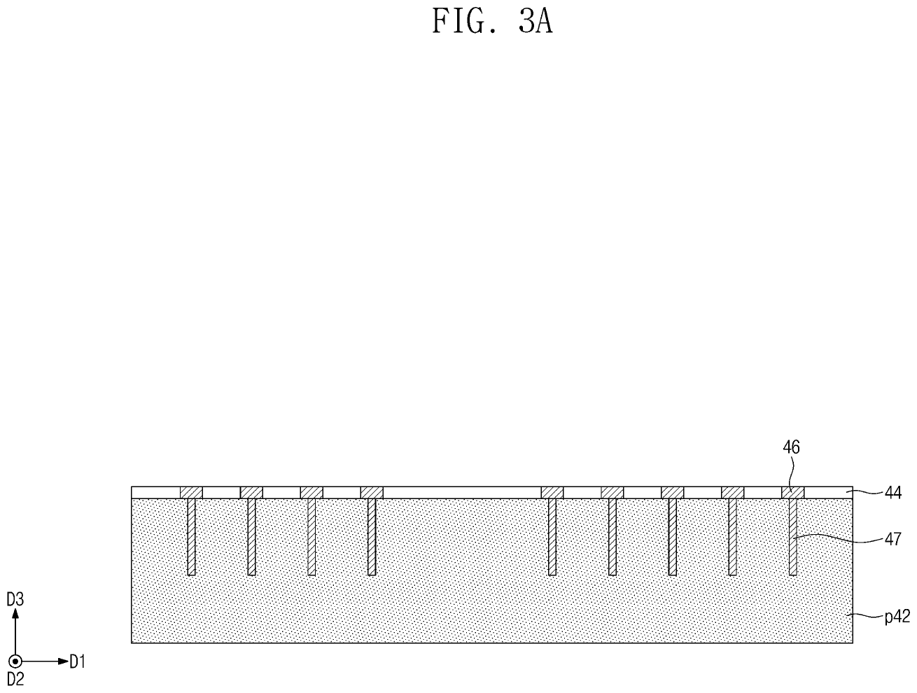

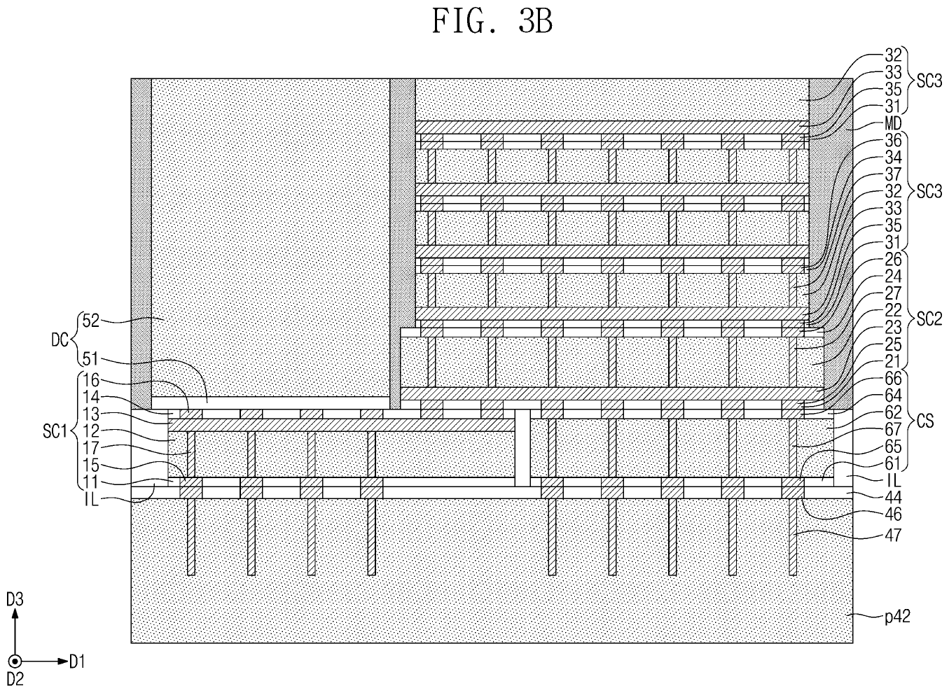

FIGS. 3A and 3B are cross-sectional views illustrating a method of manufacturing a semiconductor package according to some embodiments of the inventive concepts.

Referring to FIG. 3A, fourth through-vias 47 may be formed in a preliminary substrate p42. A fourth upper protective layer 44 may be formed on the preliminary substrate p42. Fourth upper pads 46 may be formed in the fourth upper protective layer 44.

Referring to FIG. 3B, the first semiconductor chip SC1 and the connection structure CS may be formed on the fourth upper protective layer 44. The insulating layer IL may be formed to surround the first semiconductor chip SC1 and the connection structure CS.

The second semiconductor chip SC2 may be formed on the first semiconductor chip SC1 and the connection structure CS. The third semiconductor chips SC3 may be formed on the second semiconductor chip SC2. The dummy semiconductor chip DC may be formed on the first semiconductor chip SC1. The molding layer MD may be formed. The method of forming the first semiconductor chip SC1, the connection structure CS, the insulating layer IL, the second semiconductor chip SC2, the third semiconductor chips SC3, the dummy semiconductor chip DC, and the molding layer MD may be similar to the method disclosed above with respect to FIGS. 2A and 2E.

Referring again to FIG. 1A, a lower portion of the preliminary substrate p42 may be removed to form a fourth substrate 42. The fourth through-vias 47 may be exposed by the removal of the lower portion of the preliminary substrate p42.

A fourth lower protective layer 41 may be formed to cover a bottom surface of the fourth substrate 42. Fourth lower pads 45 may be formed in the fourth lower protective layer 41. The terminal TE in contact with the fourth lower pad 45 may be formed.

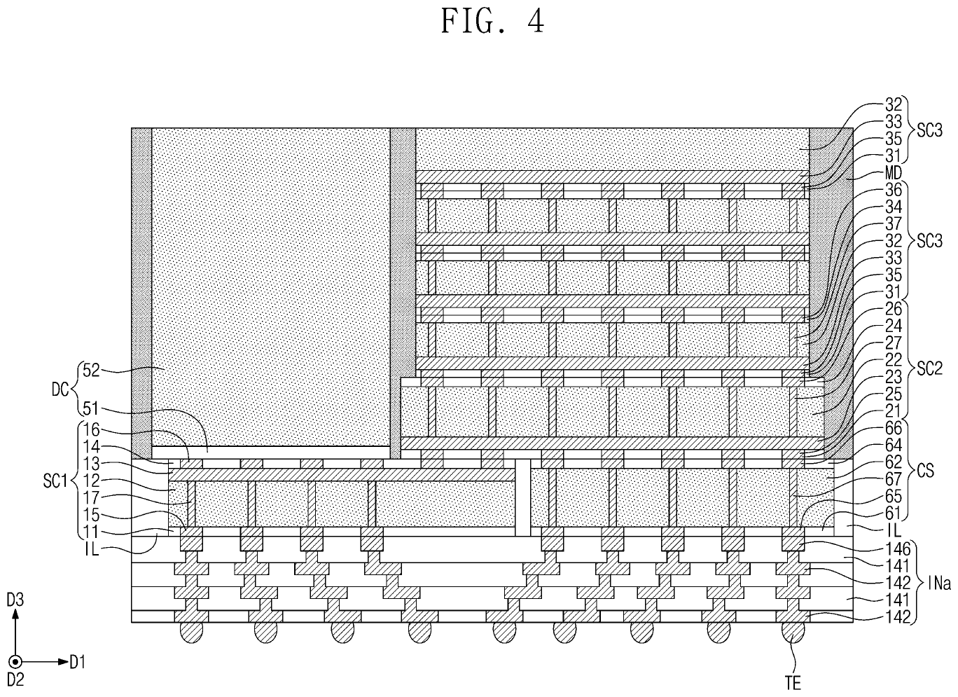

FIG. 4 is a cross-sectional view illustrating a semiconductor package according to some embodiments of the inventive concepts.

Referring to FIG. 4, an interposer INa of a semiconductor package may include fourth upper pads 146, redistribution insulating layers 141, and redistribution patterns 142. The interposer INa may be a redistribution substrate. A top surface of the fourth upper pad 146 may be in contact with the bottom surface of the lower connection pad 65 or the bottom surface of the first lower pad 15.

The redistribution insulating layers 141 may be stacked in the third direction D3. The redistribution insulating layers 141 may include a photosensitive insulating material. For example, the redistribution insulating layers 141 may include at least one of photosensitive polyimide, polybenzoxazole, a phenol-based polymer, or a benzocyclobutene-based polymer.

The redistribution patterns 142 may be surrounded by the redistribution insulating layers 141. The redistribution pattern 142 may include a via portion for vertical connection and an interconnection portion for horizontal connection. The via portion of the redistribution pattern 142 may be disposed at a higher level than the interconnection portion of the redistribution pattern 142. A width of the via portion of the redistribution pattern 142 may be less than a width of the interconnection portion of the redistribution pattern 142. Lowermost redistribution patterns 142 of the redistribution patterns 142 may be connected to the terminals TE. The redistribution patterns 142 may include a conductive material.

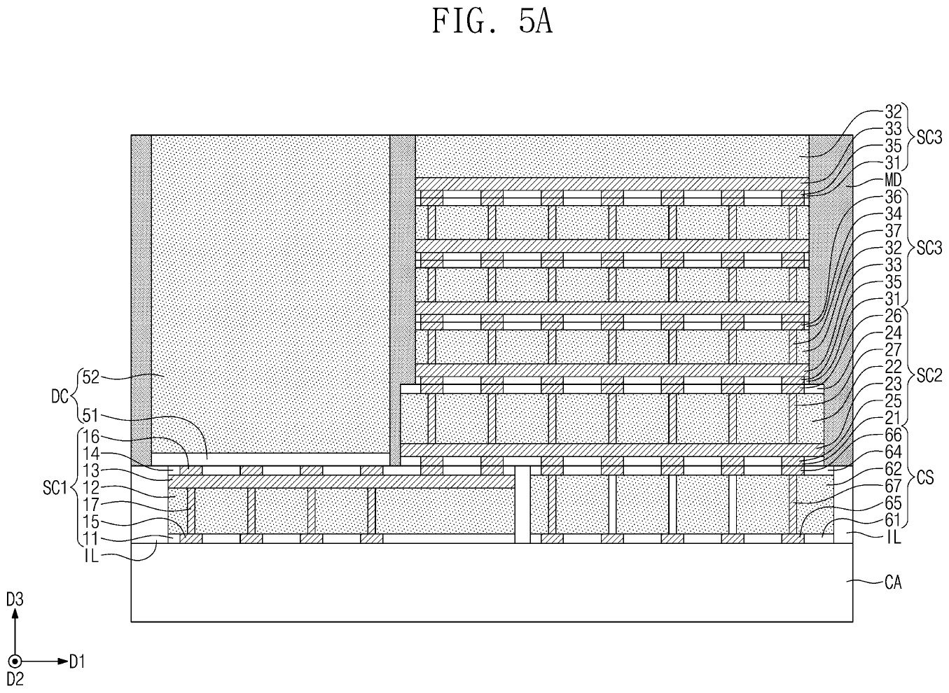

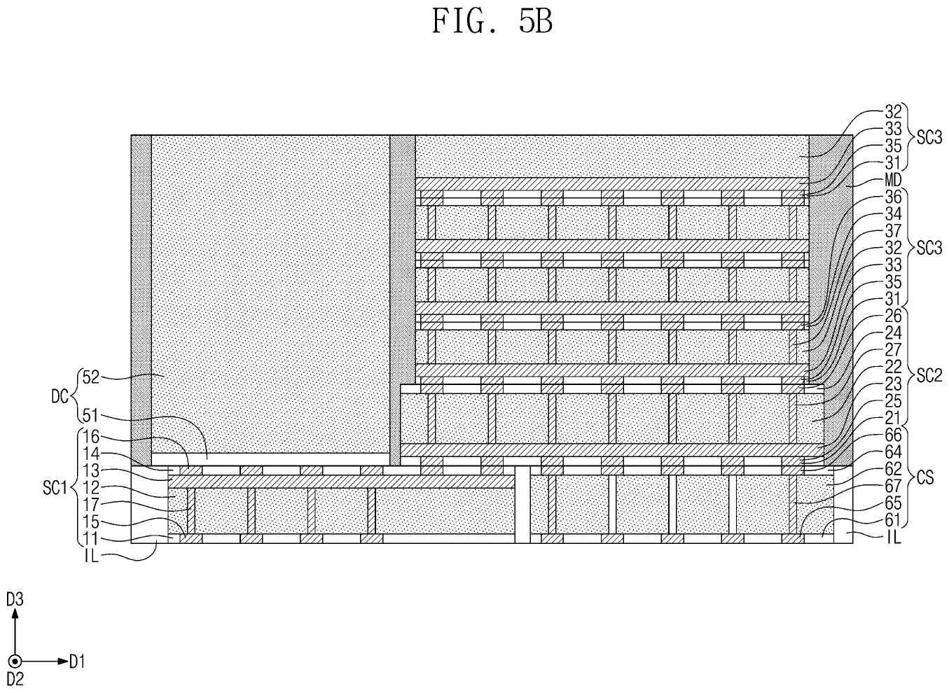

FIGS. 5A and 5B are cross-sectional views illustrating a method of manufacturing a semiconductor package according to some embodiments of the inventive concepts.

Referring to FIG. 5A, the first semiconductor chip SC1, the connection structure CS and the insulating layer IL may be formed on a carrier substrate CA in a manner similar to that as described with respect FIGS. 2A to 2E above. In some embodiments, the carrier substrate CA may include align keys for aligning the first semiconductor chip SC1 and the connection structure CS.

The second semiconductor chip SC2 may be formed on the first semiconductor chip SC1. The third semiconductor chips SC3 may be formed on the second semiconductor chip SC2. The dummy semiconductor chip DC may be formed on the first semiconductor chip SC1. The molding layer MD may be formed.

Referring to FIG. 5B, the carrier substrate CA may be removed. Bottom surfaces of the insulating layer IL, the first semiconductor chip SC1 and the connection structure CS may be exposed by the removal of the carrier substrate CA.

Referring again to FIG. 4, an interposer INa may be formed on the bottom surfaces of the insulating layer IL, the first semiconductor chip SC1 and the connection structure CS. The formation of the interposer INa may include forming fourth upper pads 146, redistribution insulating layers 141 and redistribution patterns 142 on the bottom surfaces of the insulating layer IL, the first semiconductor chip SC1 and the connection structure CS.

A terminal TE connected to the redistribution pattern 142 may be formed.

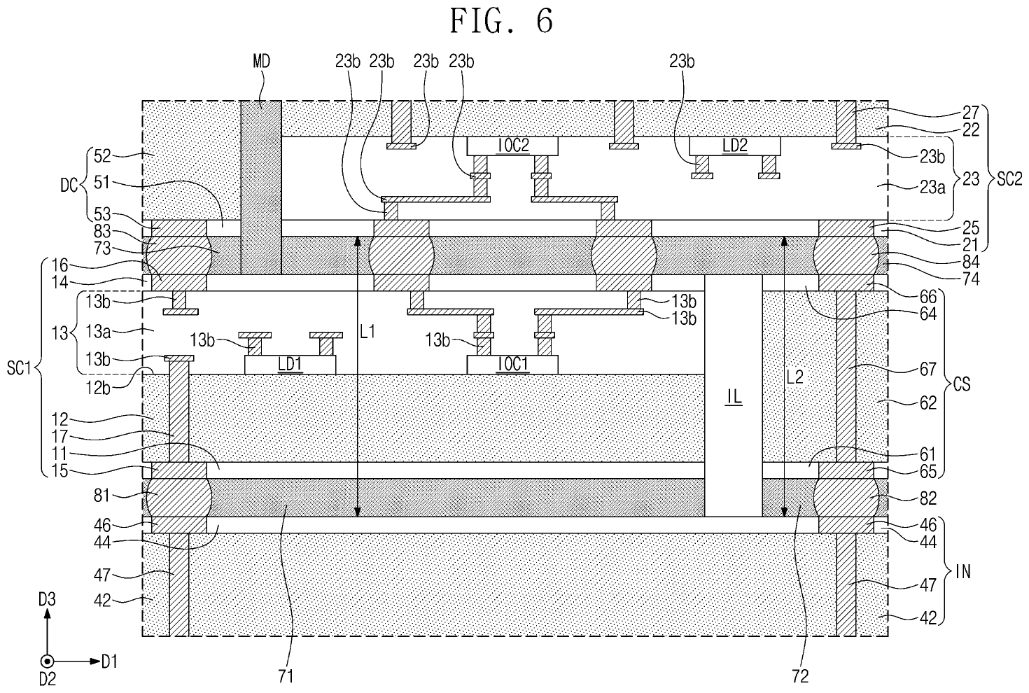

FIG. 6 is an enlarged cross-sectional view illustrating a semiconductor package according to some embodiments of the inventive concepts.

Referring to FIG. 6, a first bump 81 may be provided to connect the first lower pad 15 of the first semiconductor chip SC1 to a corresponding one of the fourth upper pads 46 of the interposer IN. A first adhesive layer 71 may be disposed between the interposer IN and the first semiconductor chip SC1. The first adhesive layer 71 may surround the first bump 81.

A second bump 82 may be provided to connect the lower connection pad 65 of the connection structure CS to a corresponding one of the fourth upper pads 46 of the interposer IN. A second adhesive layer 72 may be disposed between the interposer IN and the connection structure CS. The second adhesive layer 72 may surround the second bump 82.

The first adhesive layer 71 and the second adhesive layer 72 may be spaced apart from each other in the first direction D1. A portion of the insulating layer IL may be disposed between the first adhesive layer 71 and the second adhesive layer 72.

The dummy semiconductor chip DC may include a dummy pad 53 in the dummy protective layer 51. The dummy pad 53 may include a conductive material.

A third bump 83 may be provided to connect the dummy pad 53 of the dummy semiconductor chip DC to a corresponding one of the first upper pads 16 of the first semiconductor chip SC1. A third adhesive layer 73 may be disposed between the first semiconductor chip SC1 and the dummy semiconductor chip DC. The third adhesive layer 73 may surround the third bump 83.

A fourth bump 84 may be provided to connect a corresponding one of the second lower pads 25 of the second semiconductor chip SC2 to a corresponding one of the first upper pads 16 of the first semiconductor chip SC1 or to connect the upper connection pad 66 of the connection structure CS to a corresponding one of the second lower pads 25 of the second semiconductor chip SC2. A fourth adhesive layer 74 may be disposed between the first semiconductor chip SC1 and the second semiconductor chip SC2 and between the connection structure CS and the second semiconductor chip SC2. The fourth adhesive layer 74 may surround the fourth bump 84.

The third adhesive layer 73 and the fourth adhesive layer 74 may be spaced apart from each other in the first direction D1. A portion of the molding layer MD may be disposed between the third adhesive layer 73 and the fourth adhesive layer 74. A bottom surface of the fourth adhesive layer 74 may be in contact with a top surface of the insulating layer IL.

A distance L1 in the third direction D3 between a bottom surface of the first adhesive layer 71 and a top surface of the fourth adhesive layer 74 may be equal to a distance L2 in the third direction D3 between a bottom surface of the second adhesive layer 72 and the top surface of the fourth adhesive layer 74.

A distance in the third direction D3 between the interposer IN and the second semiconductor chip SC2 may be equal to the distance L1 in the third direction D3 between the bottom surface of the first adhesive layer 71 and the top surface of the fourth adhesive layer 74.

The distance in the third direction D3 between the interposer IN and the second semiconductor chip SC2 may be greater than the height of the first semiconductor chip SC1 and the height of the connection structure CS.

In the semiconductor package according to the embodiments of the inventive concepts, the electrical path between the input/output circuits of the semiconductor chips may be relatively short, and thus heat generated from the semiconductor package may be minimized.

The semiconductor package according to the embodiments of the inventive concepts may include the dummy semiconductor chip, and thus heat generated from the semiconductor chip may be effectively dissipated.

In the semiconductor package according to the embodiments of the inventive concepts, the pads connecting the semiconductor chips may be relatively small designed, and the bandwidth between the semiconductor chips may be relatively increased.

In the semiconductor package according to the embodiments of the inventive concepts, the design of the interposer may be simplified.

While the embodiments of the inventive concepts have been particularly shown and described, it will be understood by one of ordinary skill in the art that variations in form and detail may be made therein without departing from the spirit and scope of the attached claims.

1. A semiconductor package comprising:
an interposer;
a first semiconductor chip on the interposer;
a connection structure on the interposer; and
a second semiconductor chip on the first semiconductor chip and the connection structure,
wherein the first semiconductor chip includes
a first substrate,
a first interconnection structure on a top surface of the first substrate, and
a first input/output circuit between the first substrate and the first interconnection structure,
wherein the second semiconductor chip includes
a second interconnection structure,
a second substrate on a top surface of the second interconnection structure, and
a second input/output circuit between the second substrate and the second interconnection structure,
wherein the connection structure includes
a connection substrate, and
a connection through-via penetrating the connection substrate and electrically connecting the second semiconductor chip and the interposer, and
wherein the first input/output circuit and the second input/output circuit are electrically connected to each other.

2. The semiconductor package of claim 1, wherein the first semiconductor chip further includes an upper pad electrically connected to the first input/output circuit,
wherein the second semiconductor chip further includes a lower pad electrically connected to the second input/output circuit, and
wherein a top surface of the upper pad of the first semiconductor chip faces a bottom surface of the lower pad of the second semiconductor chip.

3. The semiconductor package of claim 2, wherein the top surface of the upper pad of the first semiconductor chip is in contact with the bottom surface of the lower pad of the second semiconductor chip.

4. The semiconductor package of claim 1, wherein the connection structure further includes an upper connection pad electrically connected to the connection through-via, and
wherein the second semiconductor chip further includes a lower pad in contact with the upper connection pad of the connection structure.

5. The semiconductor package of claim 1, wherein the second semiconductor chip overlaps with the first semiconductor chip and the connection structure in a vertical direction.

6. The semiconductor package of claim 1. further comprising:
a dummy semiconductor chip on the first semiconductor chip,
wherein the first semiconductor chip further includes an upper protective layer on a top surface of the first interconnection structure, and
wherein the dummy semiconductor chip includes a dummy protective layer in contact with a top surface of the upper protective layer of the first semiconductor chip.

7. The semiconductor package of claim 6, wherein the first semiconductor chip further comprises: an upper pad surrounded by the upper protective layer of the first semiconductor chip, and
wherein a top surface of the upper pad of the first semiconductor chip is in contact with a bottom surface of the dummy protective layer of the dummy semiconductor chip.

8. The semiconductor package of claim 7,
wherein the dummy semiconductor chip further includes a dummy pad surrounded by the dummy protective layer of the dummy semiconductor chip, and
wherein the top surface of the upper pad of the first semiconductor chip is in contact with a bottom surface of the dummy pad of the dummy semiconductor chip.

9. The semiconductor package of claim 1, wherein the interposer includes a redistribution pattern and a redistribution insulating layer surrounding the redistribution pattern, and
wherein the redistribution insulating layer includes a photosensitive insulating material.

10. A semiconductor package comprising:
an interposer;
a first semiconductor chip on the interposer;
a connection structure on the interposer; and
a second semiconductor chip on the first semiconductor chip and the connection structure,
wherein the second semiconductor chip overlaps with the first semiconductor chip and the connection structure in a vertical direction, and
wherein a height of the first semiconductor chip is equal to a height of the connection structure.

11. The semiconductor package of claim 10, wherein a top surface of the first semiconductor chip is coplanar with a top surface of the connection structure, and
wherein a bottom surface of the first semiconductor chip is coplanar with a bottom surface of the connection structure.

12. The semiconductor package of claim 10, wherein the connection structure includes
a connection substrate, and
a connection through-via penetrating the connection substrate, and
wherein the connection through-via electrically connects the second semiconductor chip to the interposer.

13. The semiconductor package of claim 12, wherein the second semiconductor chip includes
a substrate, and
a lower pad between the substrate of the second semiconductor chip and the connection substrate of the connection structure,
wherein the connection structure further includes an upper connection pad in contact with the lower pad.

14. The semiconductor package of claim 10, further comprising:
third semiconductor chips on the second semiconductor chip; and
a dummy semiconductor chip on the first semiconductor chip,
wherein the third semiconductor chips include an uppermost semiconductor chip, and
wherein a top surface of the uppermost semiconductor chip is coplanar with a top surface of the dummy semiconductor chip.

15. The semiconductor package of claim 10, wherein the first semiconductor chip includes a first input/output circuit,
wherein the second semiconductor chip includes a second input/output circuit electrically connected to the first input/output circuit, and
wherein the first input/output circuit overlaps with the second input/output circuit in the vertical direction.

16. The semiconductor package of claim 10, wherein the first semiconductor chip includes an overlapping portion overlapping with the second semiconductor chip in the vertical direction, and
wherein a width of the first semiconductor chip is equal to or greater than twice a width of the overlapping portion.

17. The semiconductor package of claim 10, wherein a distance between the interposer and the second semiconductor chip is greater than the height of the first semiconductor chip.

18. The semiconductor package of claim 10, wherein the first semiconductor chip and the connection structure are spaced apart from each other in a horizontal direction, the semiconductor package further comprising:
an insulating layer surrounding the first semiconductor chip and the connection structure,
wherein a portion of the insulating layer is disposed between the first semiconductor chip and the connection structure.

19. A semiconductor package comprising:
an interposer;
a first semiconductor chip on the interposer;
a connection structure on the interposer;
an insulating layer surrounding the first semiconductor chip and the connection structure;
a second semiconductor chip on the first semiconductor chip and the connection structure;
third semiconductor chips on the second semiconductor chip;
a dummy semiconductor chip on the first semiconductor chip; and
a molding layer surrounding the dummy semiconductor chip, the second semiconductor chip and the third semiconductor chips,
wherein the first semiconductor chip includes
a first substrate,
a first interconnection structure on a top surface of the first substrate,
a first input/output circuit between the first substrate and the first interconnection structure, and
an upper pad electrically connected to the first input/output circuit, wherein the second semiconductor chip includes
a second interconnection structure,
a second substrate on a top surface of the second interconnection structure,
a second input/output circuit between the second substrate and the second interconnection structure, and
a lower pad electrically connected to the second input/output circuit, wherein the connection structure includes
a connection substrate, and
a connection through-via penetrating the connection substrate and electrically connecting the second semiconductor chip to the interposer, and
wherein a top surface of the upper pad is in contact with a bottom surface of the lower pad.

20. The semiconductor package of claim 19, wherein a length of an electrical path connecting the first input/output circuit to the second input/output circuit is within a range from several μm to several tens μm.

21-33. (canceled)
